(19) United States
(12) Patent Application Publication
(10) Pub. No.: US 2026/0082605 A1
(43) Pub. Date: Mar. 19, 2026

(54) METHOD OF MANUFACTURING A RADIO FREQUENCY BIPOLAR TRANSISTOR AND RADIO FREQUENCY BIPOLAR TRANSISTOR

(71) Applicant: Infineon Technologies AG, Neubiberg (DE)

(72) Inventors: Dmitri Alex TSCHUMAKOW, Dresden (DE); Andreas PRIBIL, Dresden (DE); Boris BINDER, Dresden (DE); Josef BOECK, Putzbrunn (DE)

(21) Appl. No.: 19/306,336

(22) Filed: Aug. 21, 2025

(30) Foreign Application Priority Data
Sep. 17, 2024 (DE) 102024208856.0

(51) Int. Cl. H10D 10/40; H01L 21/02; H10D 10/01; H10D 62/10; H10D 62/13; H10D 62/17; H10D 62/40; H10D 62/60

(52) U.S. Cl. CPC H10D 10/40; H10D 10/051; H10D 62/115; H10D 62/133; H10D 62/137; H10D 62/177; H10D 62/40; H10D 62/60; H10P 14/27

(57) ABSTRACT

A method of manufacturing a radio frequency bipolar transistor includes fabricating a structure including a substrate having a main surface, a collector formed in the substrate, a monocrystalline base and a cavity. The collector faces the monocrystalline base in a first direction perpendicular to the main surface and the monocrystalline base faces the cavity in the first direction. A spacer layer is formed in the cavity and the spacer layer is contacting the monocrystalline base and extending in the first direction. An emitter is formed by selective epitaxial growing doped semiconductor material from a first region of the monocrystalline base wherein during the selective epitaxial growing a first sticking coefficient on the spacer layer is zero or a factor 1/10 or less of a second sticking coefficient on the monocrystalline base.

### CROSS-REFERENCE TO RELATED APPLICATION

This application claims priority to Germany Patent Application No. 102024208856.0 filed on Sep. 17, 2024, the content of which is incorporated by reference herein in its entirety.

### TECHNICAL FIELD

The present disclosure relates to radio frequency bipolar transistors and methods for manufacturing radio frequency bipolar transistors and in particular to vertical radio frequency bipolar transistors and methods for manufacturing vertical radio frequency bipolar transistors.

### BACKGROUND

Vertical radio frequency (RF) bipolar transistors are used in many applications in the mm-wave frequency region, for example in radar applications or communication applications. The manufacturing of a vertical RF bipolar transistor may be part of a BiCMOS process used to manufacture a monolithic microwave integrated circuit (MMIC) having an RF bipolar transistor as well as CMOS transistors.

In a BiCMOS process, it is desirable to reduce the number of manufacturing steps required for the RF bipolar transistor and allow an easy and flexible integration of the RF bipolar transistor manufacturing with the CMOS manufacturing while having good performance characteristics for the RF bipolar transistors.

### SUMMARY

According to one aspect, a method of manufacturing a radio frequency bipolar transistor includes fabricating a structure including a substrate having a main surface, a collector formed in the substrate, a monocrystalline base and a cavity. The collector faces the monocrystalline base in a first direction perpendicular to the main surface and the monocrystalline base faces the cavity in the first direction. A spacer layer is formed in the cavity and the spacer layer is contacting the monocrystalline base and extending in the first direction.

An emitter is formed by selective epitaxial growing doped semiconductor material from a first region of the monocrystalline base wherein during the selective epitaxial growing a first sticking coefficient on the spacer layer is zero or a factor 1/10 or less of a second sticking coefficient on the monocrystalline base.

According to a further aspect, a radio frequency bipolar transistor includes a substrate having a main surface, a collector arranged in the substrate, a monocrystalline base, wherein the collector faces the monocrystalline base in a first direction perpendicular to the main surface. The radio frequency bipolar transistor further includes a selectively grown monocrystalline emitter wherein the monocrystalline base is in contact with the selectively grown monocrystalline emitter in the first direction. A spacer layer extends from the monocrystalline base in the first direction, wherein the spacer layer is in contact with the selectively grown monocrystalline emitter and surrounds the selectively grown monocrystalline emitter with respect to a second direction parallel to the main surface.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A-1E illustrate cross-sectional views of structures in a conventional process for manufacturing a radio frequency bipolar transistor.

FIGS. 2A-2B illustrate cross-sectional views of structures in a process of manufacturing a radio frequency bipolar transistor according to one example.

FIGS. 2C-2D illustrate cross-sectional views of structures in a process of manufacturing a radio frequency bipolar transistor according to one example.

FIGS. 3A-3B illustrate cross-sectional views of structures in a process of manufacturing a radio frequency bipolar transistor according to one example.

FIGS. 4A-4L illustrate cross-sectional views of structures in a process of manufacturing a radio frequency bipolar transistor according to one example.

FIG. 5 shows a flow chart of process steps of a process of manufacturing a radio frequency bipolar transistor according to one example.

### DETAILED DESCRIPTION

The examples described herein provide a new concept for manufacturing vertical radio frequency (RF) bipolar transistors. Conventionally it is desired in vertical RF bipolar transistors to have a high emitter doping concentration to achieve a high conductivity and high current gain and maximum oscillation frequency fmax. Conventionally the necessary high doping concentration in the emitter could only be achieved by deposition conditions, which lead to a growth of the emitter layer on the complete wafer. Recent findings in epitaxial deposition may suggest that doping concentrations in ranges such as between 1×10²⁰ cm⁻³ to 1×10²¹ cm⁻³ can be achieved by selective epitaxial growth. Selective epitaxial growing (sometimes also referred to as selective area epitaxy) is an epitaxial growth process controlled by specific process parameters such that the semiconductor material grows epitaxial only on specific materials (such as a crystalline semiconductor) while in other areas having other materials such as amorphous dielectric material, the material is ideally not growing. Such doping levels are sufficient to achieve the necessary low resistance in the emitter for a high-performance transistor.

Non-selective emitter growth typically results in additional complexity of the manufacturing flow, since the unnecessary portion of the deposited emitter material must be locally removed, requiring additional process steps for such removal. This makes the already complicated integration flow of the RF transistors even more complicated.

With the new concept using selective epitaxial growing for the forming of an emitter in a high-performance vertical RF bipolar transistor, manufacturing steps can be significantly reduced. No further etching steps are required to remove excess material outside of the emitter area. It therefore avoids difficulties in integrating these additional steps in a BiCMOS process in which in addition to the vertical RF bipolar transistor also CMOS transistors are fabricated in parallel. In view of this finding, the concept proposed herein is based on using selective epitaxial growing to form the emitter of a vertical RF bipolar transistor with an emitter doping concentration in the above mentioned range. The concept can be applied in a flexible manner to semiconductor structures by using a spacer layer to restrict the epitaxial growing and to shape the resulting emitter. Furthermore, a defect rate can be reduced due to the growing restricted only to the exposed surfaces of the monocrystalline base.

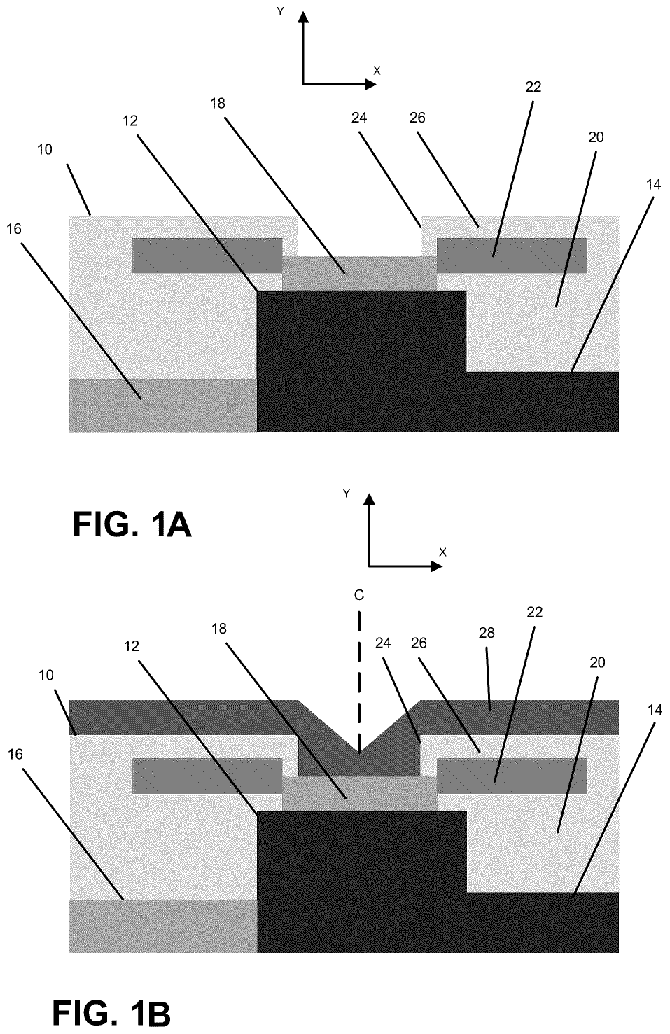

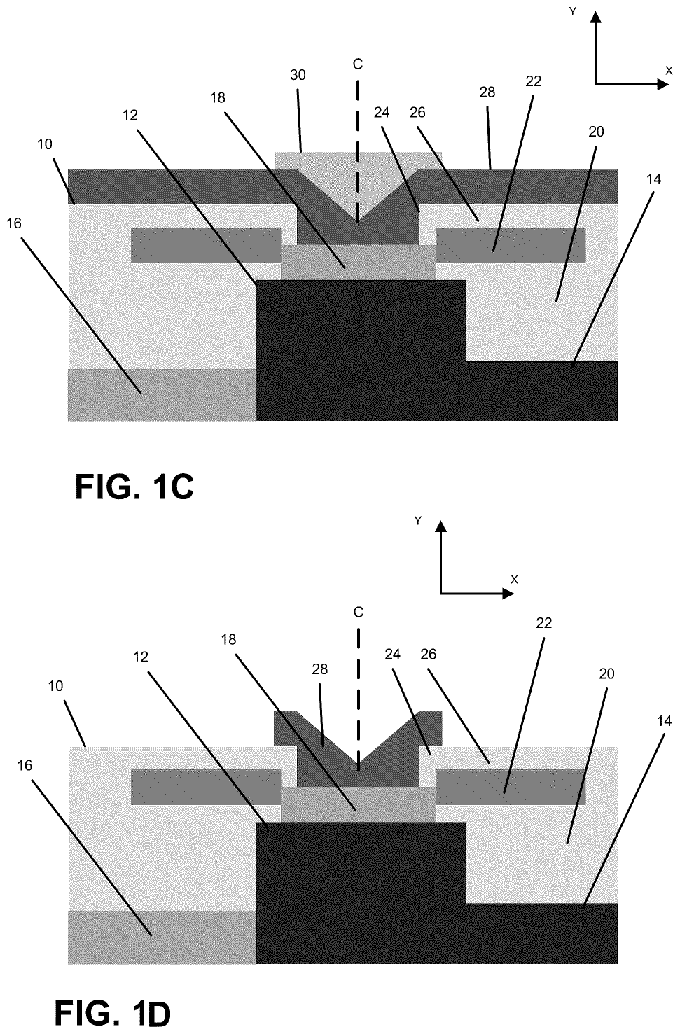

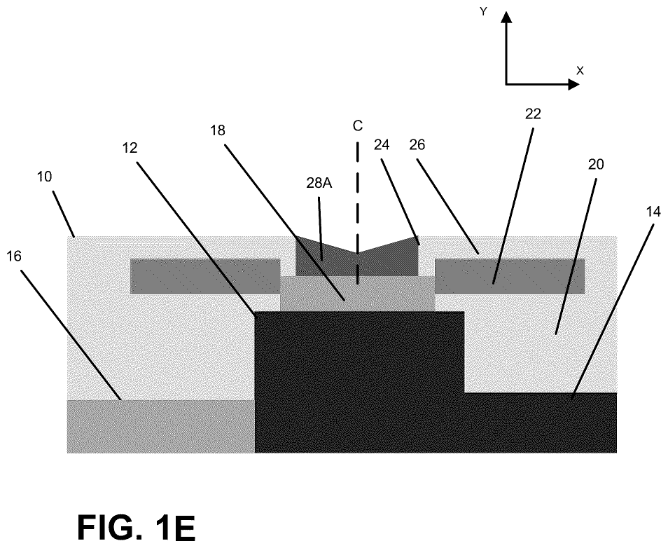

Prior to describing the concept in more detail, reference will be made to a conventional process of forming a high-performance vertical RF bipolar transistor shown in FIGS. 1A-1E.

FIG. 1A shows a cross-section of a preprocessed structure 10 as initial structure of the conventional process. The structure 10 comprises a collector 12 which is connected to a collector connection layer 14 arranged in a substrate 16. The substrate 16 may include bulk semiconductor material. An isolation region 20 including electrical isolation material such as semiconductor oxide surrounds the collector 12. A base 18 is formed above the collector 12. A base connection 22 is arranged lateral to the base 18 for providing an electrical connection to the base. A spacer layer 24 is arranged to define an emitter window area. A cover layer 26 is in contact with the spacer 24 and extends outside of the emitter window area.

Starting from the preprocessed structure 10 shown in FIG. 1A, emitter material 28 is deposited using a conventional growing process, i.e. the deposition is done on the complete wafer. As can be observed from FIG. 1B, the emitter material 28 extends in the emitter window area on the surfaces of the base 18, on the spacer layer 24 and on the surface of the cover layer 26. As a further result of this epitaxial growing, the emitter material 28 has a dip in a central region around a center axis C of the vertical RF bipolar transistor. The center axis C may for example be determined by a virtual line in the vertical direction (y-direction) through the arithmetic midpoint of an area of the emitter material 28 when viewed from the top. The vertical direction is a direction which is perpendicular to the main surface of the substrate 16.

Since the emitter material 28 is formed also on the surface of the cover layer 26, further etching steps are required to form a transistor. To this end, a mask 30 is formed on the structure as shown in FIG. 1C.

In a following step, an etching is performed using the mask 30 to remove the emitter material 28 outside of the mask area. It is to be noted that the mask 30 needs to extend beyond the inner sidewalls of the spacer layer 24 in order to avoid unintentional etching of the emitter material 28 in the emitter window area. Therefore, the remaining emitter material 28 extends not only within the emitter window area but also outside of the emitter window area on the surface of the spacer layer 24 and the cover layer 26, see FIG. 1C.

The portions of the emitter material 28 outside of the emitter window area are removed and the mask 30 is removed as shown in FIG. 1D.

Thereafter, optionally the emitter material 28 is etched back to the level of the cover layer 26 thereby forming an emitter 28A, see FIG. 1E.

It becomes clear that multiple steps are required after the deposition of the emitter material 28 in order to form the emitter 28A.

Furthermore, it becomes clear that the emitter 28A still includes a dip in the central region which in some circumstances may be unwanted or desired to be avoided.

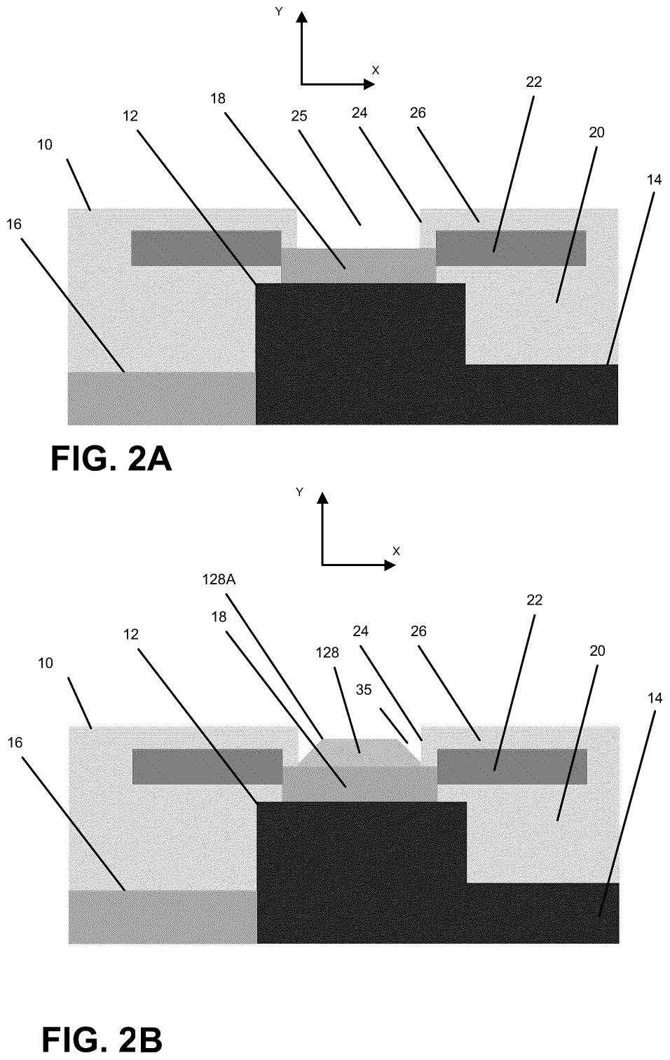

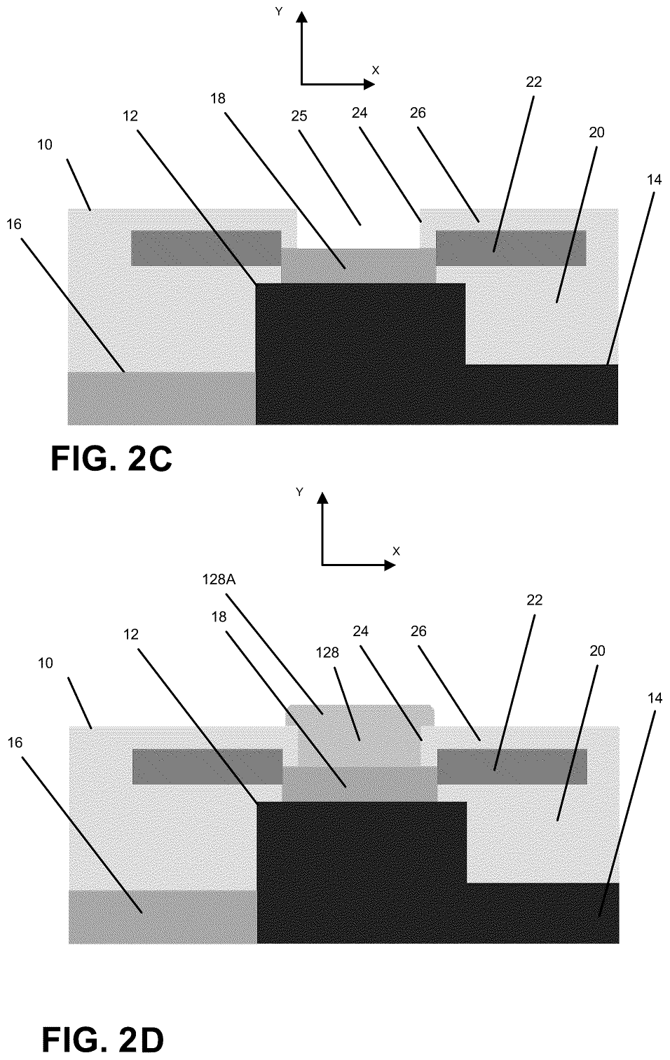

FIGS. 2A-2B show an example of a manufacturing process of a vertical RF bipolar transistor according to an example of the presented concept. The process can be part of a BiCMOS process in which in addition to the vertical RF bipolar transistor further CMOS transistors are formed. The vertical RF bipolar transistor may be a hetero-junction bipolar transistor. The vertical RF bipolar transistor may be a n-p-n transistor or a p-n-p transistor. In one example, the vertical RF bipolar transistor may have a maximum frequency of oscillation, fmax, of 100 GHz or above. In a further example, the vertical RF bipolar transistor may have a maximum frequency of oscillation, fmax, of 400 GHz or above. In another example, the vertical RF bipolar transistor may have a maximum frequency of oscillation, fmax, of 600 GHz or above.

FIG. 2A starts from the same structure 10 shown in FIG. 1A. However, distinguished from the conventional process, a selective epitaxial growing process is applied for growing emitter material 128 forming an emitter 128A restricted to the emitter window area, see FIG. 2B. In the selective epitaxial growing process, the emitter material 128 is growing from the base 18 while growing from other materials such as the dielectric material of the spacer layer 24 or the cover layer 26 is prevented. The growing conditions for the emitter material 128 are selected to ensure epitaxial growing only from the exposed surface of the base, but not from the dielectric material of the spacer layer 24 or the cover layer 26. The base 18 may in one example include Silicon-Germanium (SiGe) material.

During the selective epitaxial growing process, gases such as silane SiH4 or derivatives like SinH2n+2 (n being integer) or dichlorsilan or other gases, which can be used as precursor for the deposition of the wanted semiconductor material are introduced. The selectivity is provided by predefining a concentration of the gas such that gas particles may get in contact with the base 18 and attach thereon to form an epitaxial crystal lattice. The gas particles may also get in contact with the spacer layer 24 but do not stick on the spacer layer 24 due to the specific selectivity of the selective epitaxial growing. Gases like hydrochloric acid (HCl) may be used to modify the adhesiveness of the to be deposited particles on different materials. Such gases may in one example be added to the reaction gas. In one example, the selective epitaxial growing may include a deposition-etch process in which a non-selective deposition and etching with HCL is carried out several times in alternation. This utilizes the effect that there is a delayed start of growth on non-silica surfaces and initially only germs are formed, which are then removed again by etching. The growth rate or sticking coefficient on the base material is therefore significant different to the growth rate or sticking coefficient on the material of the spacer layer 24 during the selective epitaxial growing. As a result, emitter material 128 is prevented from sticking on or growing from the spacer layer 24. A sticking coefficient on the spacer layer 24 may be zero or not exceeding a factor 1/10 of a sticking coefficient on the monocrystalline base.

The spacer layer 24 may have a thickness in a range between 5 nm and 100 nm. The spacer layer 24 may in one example include one material which may have been formed by a single deposition process. In other examples the spacer layer 24 may include multiple sub-layers of different material which may be formed by multiple deposition processes. The spacer layer 24 may in some examples include amorphous dielectric material such as oxide material (e.g., SiO2) or nitride material (e.g., SiN4).

To achieve selective epitaxial growing, the material of the cover layer 26 may also include amorphous dielectric material such as oxide material (e.g., SiO2) or nitride material (e.g., SiN4). Accordingly, a sticking coefficient on the cover layer 26 may be zero or not exceeding a factor 1/10 of a sticking coefficient on the monocrystalline base.

A temperature during the selective epitaxial growing may be between 450° and 1050° C. Pressure may be between 10⁻³ and 10² mbar. A gas flow rate may be between 1 and 2000 standard cubic centimeters per minute. Chemical vapor deposition (CVD), molecular beam epitaxy (MBE) or metalorganic chemical vapor deposition (MOCVD) may be used.

The emitter material 128 formed by the selective epitaxial growing may be doped silicon material. In one example, the dopant may be an n-type dopant such as Arsenic (As) or Phosphorus (Ph). In some examples, Carbon (C) may be added to the dopant. The selective epitaxial growing may be controlled such that the emitter material 128 is growing in one example with a net doping concentration between 1×10²⁰ cm⁻³ and 1×10²¹ cm⁻³.

Using the selective epitaxial growing process, the emitter 128A can be formed in one step as shown in FIG. 2B. In examples, the emitter 128A needs no further steps such as removing of the emitter material 128 outside of the emitter window area or an etching back of the emitter material 128. Accordingly, a much better integration into manufacturing processes can be achieved since additional etching steps are avoided. Furthermore, manufacturing steps can be reduced and production costs can be lowered. An additional advantage is, that the emitter is grown only on bipolar transistor areas and not on other areas like CMOS transistors, where the later necessary removal of the emitter layer could lead to damage of those devices due to the necessary etch process for layer removal.

As can be seen from FIG. 2B, the forming of the emitter 128A by selective epitaxial growing may result in a shape of the emitter 128A in which the surface of the emitter 128A facing away from the base 18 (upper surface) has a smaller dimension in a lateral direction (x-direction) than the surface of the emitter 128A facing towards the base 18 (lower surface). The lateral direction is a direction parallel to a main surface of the substrate 16. The dimension of the emitter 128A in the lateral direction may vary in a range between 30 nm and 500 nm for high-frequency transistors.

The emitter 128A may be arranged in the lateral direction between respective opposing portions of the spacer layer 24 and therefore be surrounded by the spacer layer 24. A surface of a lower section of the emitter 128A is directly in contact with a surface of the spacer layer 24. A lateral surface of an upper section of the emitter 128A is not directly in contact with a surface of the spacer layer 24. As a consequence a gap 35 is formed in the lateral direction between the upper section of the emitter 128A and the spacer layer 24 after the selective epitaxial growing of the emitter 128A. Due to the gap 35, the emitter 128A may in one example have a trapezoid-like shape. Such shape would bring an additional advantage by increasing the area for silicide formation thus reducing the emitter resistance. The gap 35 may be later filled with contact material to provide an electrical contact for the emitter 128A. Furthermore, it can be observed that the emitter 128A may be formed to extend in the vertical direction not beyond the spacer layer 24.

Accordingly, a vertical RF bipolar transistor is formed having a collector 12 arranged in the substrate 16 and a monocrystalline base 18 facing the collector 12 in the vertical direction. The selectively grown monocrystalline emitter 128A is in contact with the monocrystalline base 18 in the vertical direction and the spacer layer 24 extends from the monocrystalline base 18 in the vertical direction. The spacer layer 24 is in contact with the selectively grown monocrystalline emitter 128A and surrounds the selectively grown monocrystalline emitter 128A with respect to the lateral direction.

FIGS. 2C-2D show a further example of a process of manufacturing a vertical RF bipolar transistor according to the disclosed concept. FIG. 2C starts from the same structure 10 as shown in FIG. 1A and FIG. 2A. Similar to the concept of FIG. 2A, a selective epitaxial growing process is applied to form the emitter 128A in one step as shown in FIG. 2D. Distinguished from FIG. 2B, the selective epitaxial growing process is controlled such that the emitter 128A extends in the vertical direction beyond the spacer layer 24. Furthermore, the selectively grown monocrystalline emitter 128A extends in the lateral direction on the upper side of the spacer layer 24 and/or the upper side of the protection layer 26 beyond the cavity 25. This allows that the selective epitaxial grown monocrystalline emitter 128A can be formed with reduced vertical dimension. A reduction of the vertical dimension of the emitter 128A may be required for example in future advanced CMOS nodes as the base connection layer and the dielectric layer on top of the base connection layer become thin as required in advanced CMOS nodes.

As the emitter 128A is siliconized later in order to establish a good electrical contact, a part of the emitter 128A is converted into silicide material and the emitter 128A is further reduced by several 10 nm in the vertical direction. If the vertical dimension of the emitter 128A becomes too thin after siliconizing, the emitter-base space charge zone may touch the silicide and leakage currents will occur.

In addition, the emitter 128A is provided with a contact from above, which has a certain width depending on the process node. If the emitter, which is laterally restricted within the spacer layer 24, becomes narrower than this contact width, it can no longer be contacted without etching past the emitter and creating a short circuit to the base connection. In order to avoid the above, according to some examples the selective epitaxial growing of the 128A emitter is controlled to extend beyond the spacer layer 24.

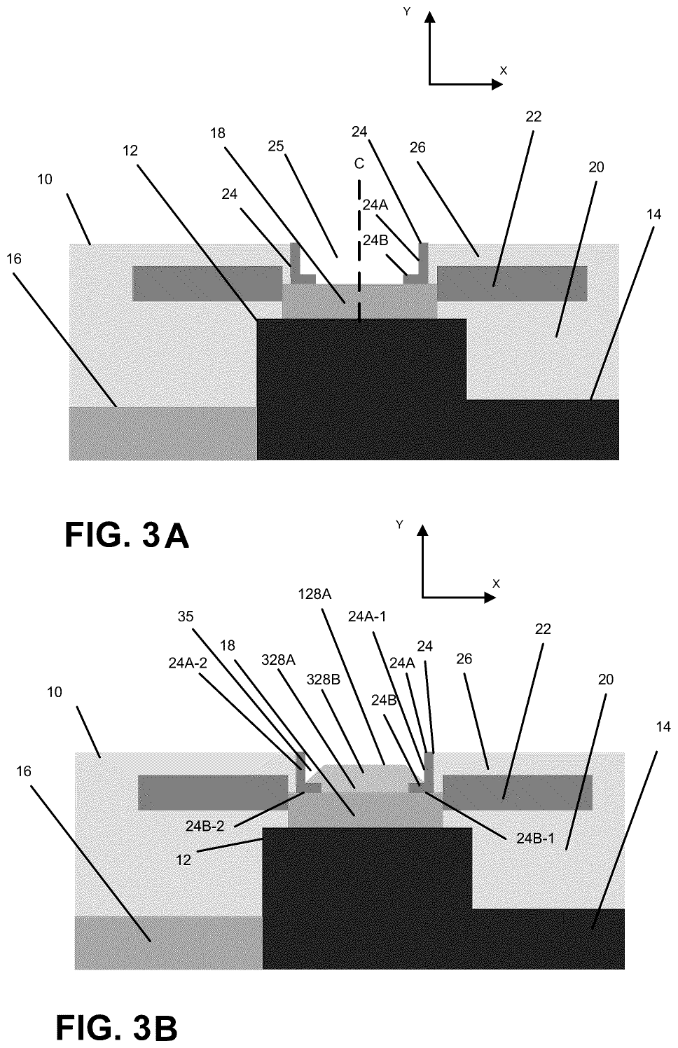

FIGS. 3A-3B show a further example of a process of manufacturing a vertical RF bipolar transistor according to the disclosed concept. The process can be part of a BiCMOS process in which in addition to the vertical RF bipolar transistor further CMOS transistors are formed. In FIG. 3A a structure 10 is prepared in which the spacer layer 24 includes a first section 24A which extends in the vertical direction (y-direction) and a second section 24B which extends in the lateral direction (x-direction). A distance in the lateral direction between the second section 24B of the spacer layer 24 and the center axis C of the RF bipolar transistor is smaller than a distance in the lateral direction between the first section 24A and the center axis C of the RF bipolar transistor.

The spacer layer 24 may in the cross-sectional view have an L-shape as shown in FIG. 3A. The spacer layer 24 may in some examples further include a stack of layers instead of a single layer.

The second section 24B of the spacer layer 24 is in direct contact with the base 18 and restricts the area of epitaxial growing emitter material 128 from the upper surface of the base 18. The second section 24B therefore defines the base-emitter contact area between the base 18 and the emitter material 128 formed using selective epitaxial growing.

FIG. 3B shows the structure of FIG. 3A after the selective epitaxial growing of the emitter 128A. It can be observed that a space between laterally opposing portions 24B-1 and 24B-2 of the second section 24B of the spacer layer 24 is completely filled with emitter material 128. The emitter 128A may therefore have a substantially rectangular first section 328A in this area. The first section 328A is in the vertical direction in contact with the base 18 and in the lateral direction in contact with the second section 24B of the spacer layer 24. The emitter 128A has a second section 328B with a trapezoid-like shape between laterally opposing portions 24A-1 and 24A-2 of the first section 24A of the spacer layer 24. The rectangular first section 328A is closer to the substrate 16 than the second section 328B.

As can be observed, the second section 328B of the emitter 128A is in contact and extending on an upper surface of the second section 24B of the spacer layer 24. A lateral dimension (dimension in x direction) of the emitter 128A is widening at the level of the upper surface of the second section 24B when moving in a direction pointing away from the substrate 16 (y-axis direction).

Moving further in the direction pointing away from the substrate 16, the lateral dimension of the second section 328B of the emitter 128A is decreasing. Accordingly, a gap 35 in the lateral direction may be formed between the second section 328B of the emitter 128A and the first section 24A of the spacer layer 24. In other words, the selective epitaxial growing of doped semiconductor material results in the emitter 128A being arranged between respective opposing portions of the spacer layer 24 such that a surface of the first section 328A of the emitter 128A is directly contacting a surface of spacer layer 24 in the lateral direction and a surface of a second section 328B of the emitter 128A is not directly contacting a surface of the spacer layer 24 in the lateral direction. In some examples, the emitter 128A therefore has a mushroom-like shape. The emitter 128A may in some examples be completely arranged within the cavity 25 and the emitter 128A may in the vertical direction not extend beyond the spacer layer 24 as shown in FIG. 3B. In some examples, the emitter 128A may however in a manner similar to FIGS. 2C and 2D extend in vertical and lateral direction beyond the cavity 25 as described with respect to FIGS. 2C and 2D.

It is to be noted that the second section 24B of the spacer layer 24 extending in the lateral direction is tailoring the shape of the emitter 128A. The lateral extension of the second section 24B of the spacer layer 24 defines the lateral size of the first section 328A while the vertical extension of the second section 24B of the spacer layer 24 defines the vertical size of the first section 328A. Accordingly, by varying the lateral and vertical extension of the second section 24B of the spacer layer 24, the size of the first section 328A can be varied according to the desired shape of the emitter 128A. This allows a flexible concept to manufacture tailor-made emitter structures without significant changes in the manufacturing process.

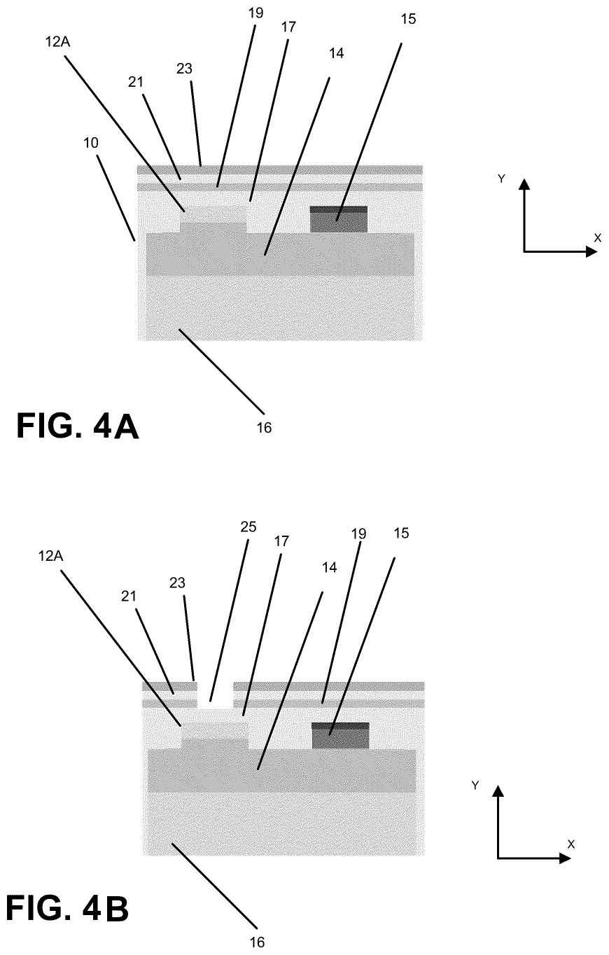

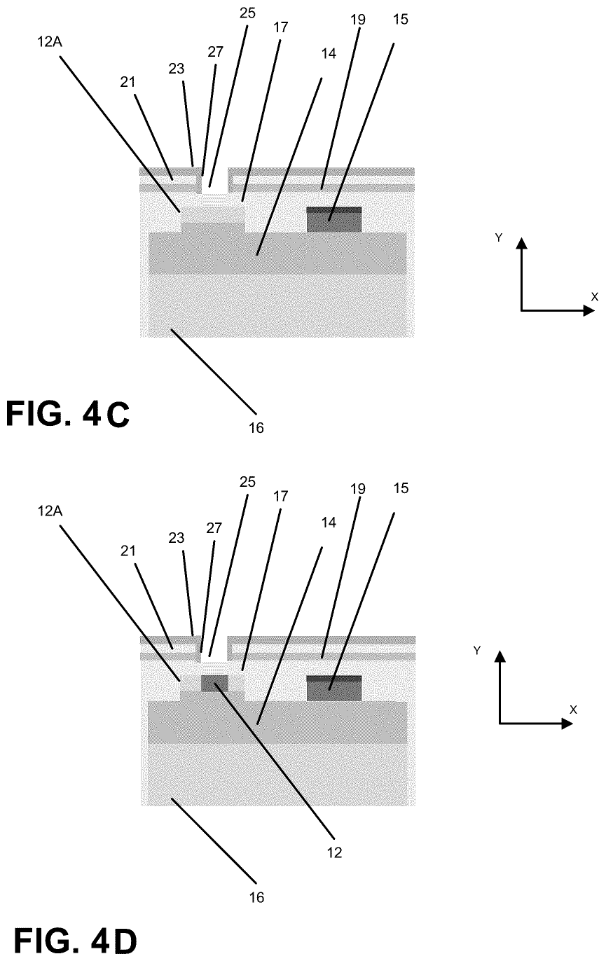

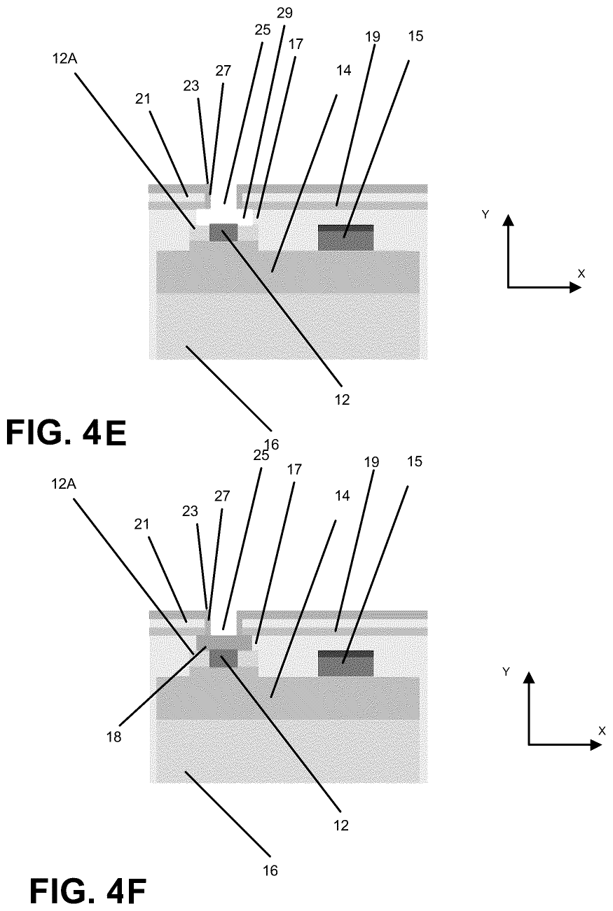

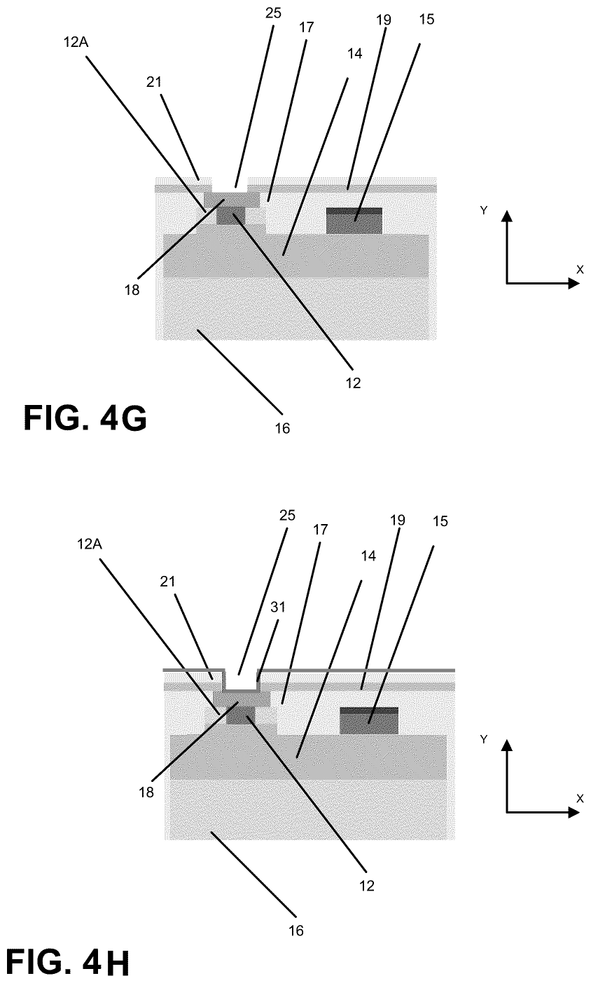

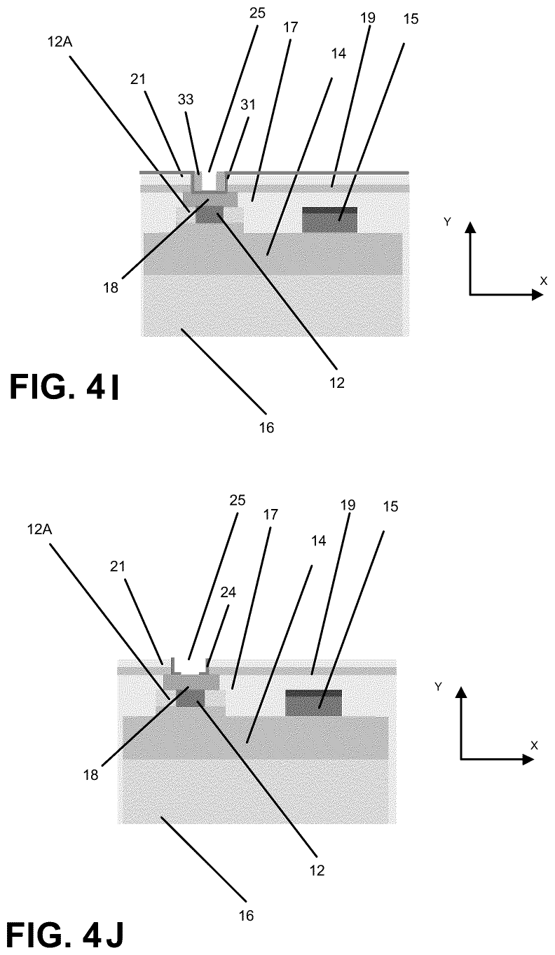

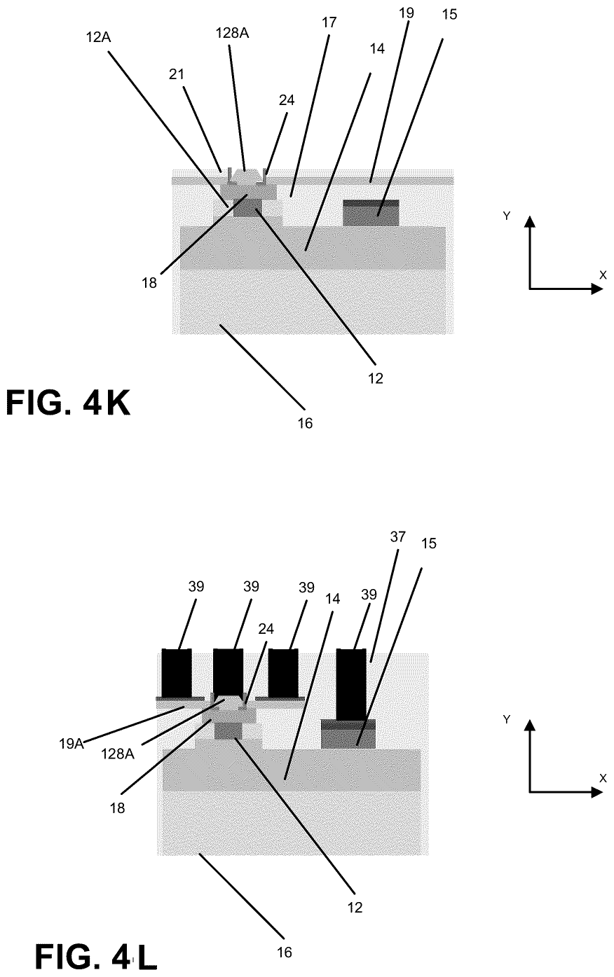

Referring now to FIGS. 4A-4L, a further example of a process of manufacturing a vertical RF bipolar transistor will be described. The process can be part of a BiCMOS process in which in addition to the vertical RF bipolar transistor further CMOS transistors are formed.

FIG. 4A shows a cross-sectional view of an initial preprocessed structure 10 in which a collector region 12A is formed in the substrate 16. The collector region 12A is connected to a collector connection layer 14 which connects the collector region 12A with a collector contact region 15. The substrate 16 may include lightly p- or n-doped silicon with a net doping in a range between 1×10¹⁴ and 1×10¹⁵ cm⁻³. In the case of npn bipolar transistors, the collector connection layer 14 may be n-doped with a doping concentration higher than the doping concentration of the substrate 16. Furthermore, the collector contact region 15 may be n-doped.

A stack of layers is arranged above the collector region 12A. The stack of layers includes a first isolation layer 17 in direct contact with the collector region 12A and extending in the lateral direction on the collector region 12A. The first isolation layer 17 may include for example silicon oxide material. A conductive layer 19 including for example polycrystalline doped semiconductor material is formed above the first isolation layer 17 and extends in the lateral direction on the first isolation layer. A second isolation layer 21 including for example oxide material and a third isolation layer 23 including for example nitride material are formed above the conductive layer 19. In other examples, a single second isolation layer 21 may be formed instead of the second and third isolation layers 21 and 23.

In a following step, a cavity 25 is etched into the stack of layers above the collector region 12A. The etching removes respective portions of the second and third isolation layers 21, 23 and conductive layer 19. The etching stops on the first isolation layer 17. Accordingly, the cavity 25 extends from an upper surface of the first isolation layer 17 to the level of the upper surface of the third isolation layer 23 as is shown in FIG. 4B.

In a following step, a first spacer layer 27 extending in a vertical direction on inner surfaces of the cavity 25 and further extending on the third isolation layer 23 is formed, see FIG. 4C. The first spacer layer 27 may include electric isolation material such as silicon nitride for example. A thickness of the first spacer layer 27 may be in a range between 10 and 100 nm. In some examples, the first spacer layer 27 may include a stack of sub-layers.

After the forming of the first spacer layer 27, a doping of the collector region 12A is performed to form the collector 12 as shown in FIG. 4D. The first spacer layer 27 defines a window area allowing to implant dopants in the collector 12 via the cavity 25. The collector 12 is formed by doping through the first isolation layer 17 in the window area.

After the forming of the collector 12, an etching is performed via the window area to partially remove the first isolation layer 17. The first isolation layer 17 is removed in an area defined by the first spacer layer 27. Furthermore, an under-etching is performed to further remove the first isolation layer 17 also below the first spacer layer 27 and below a portion of the conductive layer 19. After the etching, an empty space 29 is formed in order to expose the collector region 12A including the collector 12, see FIG. 4E. The empty space 29 extends at an outer end between the first isolation layer 17 and the substrate 16 and between the first spacer layer 27 and the substrate 16 with respect to the vertical direction.

In a next step, the base 18 is formed by epitaxial growing monocrystalline material on the exposed collector region 12A. The base completely fills the empty space 29 exposed by the previous etching of the first isolation layer 17. At an outer end of the previous empty space 29, an upper surface of the base 18 extends to a lower surface of the conductive layer 19 and is in direct contact with the conductive layer 19 to establish an electrical connection, see FIG. 4F.

After the growing of the base 18, the first spacer layer 27 and the third isolation layer 23 are removed as shown in FIG. 4G.

Distinguished from the above, in some examples, the first spacer layer 27 may not be removed and the spacer layer 24 may be formed on the first spacer layer 27.

In a following step, a layer 31 is formed in the cavity 25. The layer 31 may include in one example silicon oxide material. The layer 31 extends in a lateral direction on the upper surface of the base 18 and in a vertical direction on the exposed ends of the first isolation layer 17 and the conductive layer 19 as shown in FIG. 4H. The layer 31 may be formed including a deposition on the entire surface of the wafer.

Furthermore a layer 33 is formed as spacer on the side surfaces of the layer 31 in the cavity 25, see FIG. 4I. The layer 33 may in one example include nitride material such as Si3N4. The layer 33 may be formed using multiple steps not shown here including a deposition on the entire surface of the wafer and an etching such that the layer 33 remains as spacer on the side walls of the layer 31 in the cavity 25.

Portions of the layer 31 are removed at the bottom of the cavity and on top of the second isolation layer 21 by etching the layer 31 isotropically, for example with HF. The layer 33 protects the layer 31 formed by oxide material. The removing of the portions of the layer 31 structures the layer 31 and forms the spacer layer 24 as the structured layer 31. After the etching, the layer 33 is removed and the spacer layer 24 having an L-shape is exposed as shown in FIG. 4J. Optionally, the layer 33 may be not removed.

After the forming of the spacer layer 24, the structure is prepared for the selective epitaxial growing of the emitter 128A. FIG. 4K shows the structure after the emitter 128A is formed with the cavity 25 between the emitter 128A and the spacer layer 24. As described earlier, the spacer layer 24 defines the shape and size of the emitter 128A. FIG. 4K shows the emitter 128A not to extend beyond the cavity 25. However, in some examples, the emitter 128A may in a manner similar to FIG. 2D extend in vertical and lateral direction beyond the cavity 25.

In the following processing steps are performed to provide contacts for the collector 12, base 18 and emitter 128A. The processing steps include a structuring of the conductive layer 19 to form a base connection 19A, a deposition of further isolation material 37 on the second isolation layer 21 to increase the thickness and forming of contact holes 39 to allow access to the base connection 19A, the collector contact region 15 and the top surface of the emitter 128A. The contact holes 39 are filled with conductive material to establish the electrical connection. As can be observed from FIG. 4L, the former cavity 25 is also filled with the conductive material to establish an electrical connect with the emitter 128A.

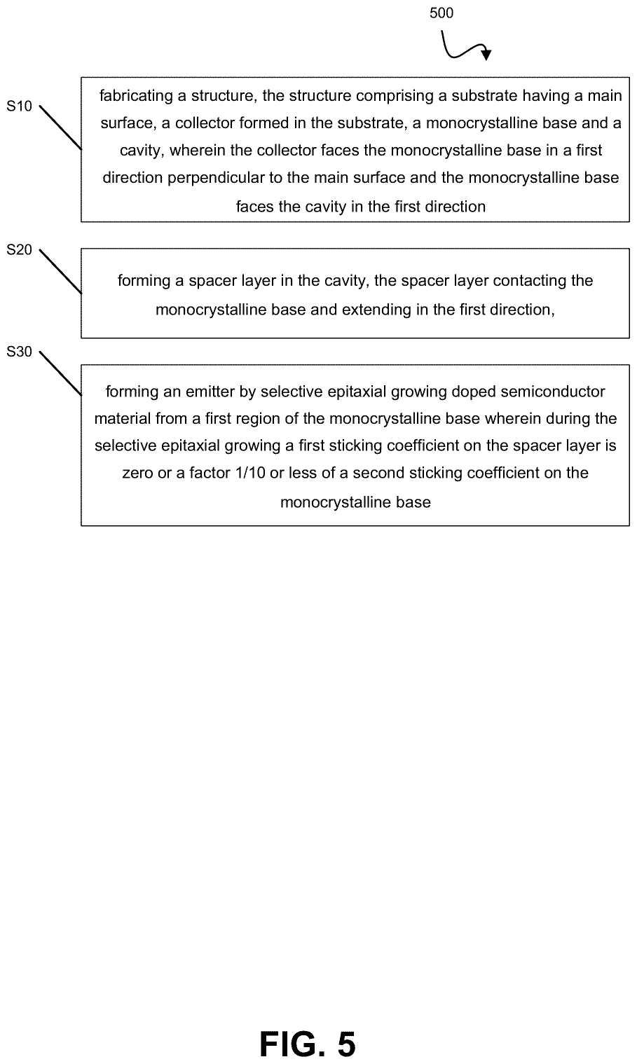

A flow chart 500 of example process steps of a process for manufacturing a radio frequency bipolar transistor according to the disclosed concept will now be described with respect to FIG. 5.

Step S-10 of the flow chart 500 includes a fabricating of a structure, the structure comprising a substrate having a main surface, a collector formed in the substrate, a monocrystalline base and a cavity, wherein the collector faces the monocrystalline base in a first direction perpendicular to the main surface and the monocrystalline base faces the cavity in the first direction.

In step S20, a spacer layer is formed in the cavity, the spacer layer contacting the monocrystalline base and extending in the first direction.

An emitter is formed by selective epitaxial growing doped semiconductor material from a first region of the monocrystalline base wherein during the selective epitaxial growing a first sticking coefficient on the spacer layer is zero or a factor 1/10 or less of a second sticking coefficient on the monocrystalline base, see step S30.

In addition to the above examples, the following examples of the concept described herein are presented.
Example 1 is a method of manufacturing a radio frequency bipolar transistor, the method comprising:
   fabricating a structure, the structure comprising a substrate having a main surface, a collector formed in the substrate, a monocrystalline base and a cavity, wherein the collector faces the monocrystalline base in a first direction perpendicular to the main surface and the monocrystalline base faces the cavity in the first direction,
   forming a spacer layer in the cavity, the spacer layer contacting the monocrystalline base and extending in the first direction,
   forming an emitter by selective epitaxial growing doped semiconductor material from a first region of the monocrystalline base wherein during the selective epitaxial growing a first sticking coefficient on the spacer layer is zero or a factor 1/10 or less of a second sticking coefficient on the monocrystalline base.
Example 2 is the method according to example 1, wherein the spacer layer is formed such that a first section of the spacer layer extends in the first direction and a second section of the spacer layer is in contact with the monocrystalline base and extends in a second direction parallel to the main surface to define a base-emitter contact area, wherein a distance in the second direction between the second section of the spacer layer and a center axis of the radio frequency bipolar transistor is smaller than a distance in the second direction between the first section of the spacer layer and the center axis of the radio frequency bipolar transistor.
Example 3 is the method according to example 1 or 2, wherein forming the emitter by selective epitaxial growing includes selective epitaxial growing doped semiconductor material in the first direction not beyond the spacer layer.
Example 4 is the method according to example 1 or 2, wherein forming the emitter by selective epitaxial growing includes selective epitaxial growing doped semiconductor material in the first direction beyond the spacer layer.
Example 5 is the method according to any of the preceding examples, wherein the spacer layer has a thickness between 5 and 100 nm.
Example 6 is the method according to any of the preceding examples, wherein fabricating of the structure comprises forming a first isolation layer extending on a collector region in a second direction parallel to the main surface, forming a conductive layer extending on the first isolation layer in the second direction and forming a second isolation layer extending on the conductive layer in the second direction,
   etching a portion of the second isolation layer and a portion of the first conductive layer to form the cavity,
   forming a first spacer layer on a sidewall of the cavity, the first spacer layer defining a first window area,
   forming the collector in the collector region by doping the collector region through the first isolation layer in the first window area,
   etching a portion of the first isolation layer to form an empty space in the first isolation layer exposing the collector, wherein the empty space extends, when viewed in the first direction, between the first spacer layer and the substrate,
   forming the monocrystalline base by epitaxially growing monocrystalline material on the collector region to fill the empty space in the first isolation layer.
Example 7 is the method according to example 6, further comprising removing the first spacer layer and forming the spacer layer on a sidewall of the cavity.
Example 8 is the method according to example 6, further comprising forming the spacer layer on the first spacer layer.
Example 9 is the method according to any of the preceding examples, wherein the selective epitaxial growing of doped semiconductor material forms the emitter between respective opposing portions of the spacer layer with a gap between the spacer layer and the doped semiconductor material.
Example 10 is the method according to any of the preceding examples, wherein during the forming of the emitter a cover layer is arranged on an area outside of the emitter, wherein during the selective epitaxial growing a third sticking coefficient on the cover layer is zero or a factor 1/10 or less of the second sticking coefficient on the monocrystalline base.
Example 11 is the method according to any of the preceding examples, wherein the selective epitaxial growing is based on a molecular beam epitaxy or vapor deposition, wherein during the selective epitaxial growing a dopant is added to provide a net doping concentration of the emitter in a range between 1×10²⁰ cm⁻³ and 1×10²¹ cm⁻³.
Example 12 is the method according to any of the preceding examples, wherein the selective epitaxial growing is based on a silane-based epitaxy, wherein the selectivity is provided by predefining a concentration of a silane gas in the silane-based epitaxy and/or using hydrochloric acid.
Example 13 is the method according to any of the preceding examples, wherein the spacer layer comprises silicon oxide or silicon nitride.
Example 14 is a radio frequency bipolar transistor comprising:
   a substrate having a main surface,
   a collector arranged in the substrate,
   a monocrystalline base, wherein the collector faces the monocrystalline base in a first direction perpendicular to the main surface,
   a selectively grown monocrystalline emitter, wherein the monocrystalline base is in contact with the selectively grown monocrystalline emitter in the first direction,
   a spacer layer extending from the monocrystalline base in the first direction, wherein the spacer layer is in contact with the selectively grown monocrystalline emitter and surrounds the selectively grown monocrystalline emitter with respect to a second direction parallel to the main surface.
Example 15 is the radio frequency bipolar transistor according to example 14, wherein a net doping concentration of the selectively grown monocrystalline emitter is between 1×10²⁰ cm⁻³ and 1×10²¹ cm⁻³.
Example 16 is the radio frequency bipolar transistor according to any of examples 14 to 15, wherein a first section of the spacer layer extends in the first direction and a second section of the spacer layer is in contact with the monocrystalline base and extends in a second direction parallel to the main surface, wherein a distance in the second direction between the second section of the spacer layer and a center axis of the radio frequency bipolar transistor is smaller than a distance in the second direction between the first section of the spacer layer and the center axis of the radio frequency bipolar transistor.
Example 17 is the radio frequency bipolar transistor according to example 16, wherein an extension of the selectively grown monocrystalline emitter in the second direction is in a first section of the selectively grown monocrystalline emitter smaller than in a second section of the selectively grown monocrystalline emitter, the first section being closer to the substrate than the second section.
Example 18 is the radio frequency bipolar transistor according to any of examples 14 to 17, wherein the radio frequency bipolar transistor is configured for a maximum frequency of oscillation, fmax, equal to or above 100 GHz.
Example 19 is the radio frequency bipolar transistor according to any of examples 14 to 18, wherein a dimension of the selectively grown monocrystalline emitter in a second direction parallel to the main surface of the substrate is in a range between 50 and 500 nm.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

1. A method of manufacturing a radio frequency bipolar transistor, the method comprising:
fabricating a structure, the structure comprising a substrate having a main surface, a collector formed in the substrate, a monocrystalline base and a cavity, wherein the collector faces the monocrystalline base in a first direction perpendicular to the main surface and the monocrystalline base faces the cavity in the first direction,
forming a spacer layer in the cavity, the spacer layer contacting the monocrystalline base and extending in the first direction, and
forming an emitter by selective epitaxial growing doped semiconductor material from a first region of the monocrystalline base wherein during the selective epitaxial growing a first sticking coefficient on the spacer layer is zero or a factor 1/10 or less of a second sticking coefficient on the monocrystalline base.

2. The method according to claim 1, wherein the spacer layer is formed such that a first section of the spacer layer extends in the first direction and a second section of the spacer layer is in contact with the monocrystalline base and extends in a second direction parallel to the main surface to define a base-emitter contact area, and
wherein a distance in the second direction between the second section of the spacer layer and a center axis of the radio frequency bipolar transistor is smaller than a distance in the second direction between the first section of the spacer layer and the center axis of the radio frequency bipolar transistor.

3. The method according to claim 1, wherein forming the emitter by selective epitaxial growing includes selective epitaxial growing doped semiconductor material in the first direction not beyond the spacer layer.

4. The method according to claim 1, wherein forming the emitter by selective epitaxial growing includes selective epitaxial growing doped semiconductor material in the first direction beyond the spacer layer.

5. The method according to claim 1, wherein the spacer layer has a thickness between 5 and 100 nm.

6. The method according to claim 1, wherein fabricating of the structure comprises:
forming a first isolation layer extending on a collector region in a second direction parallel to the main surface, forming a conductive layer extending on the first isolation layer in the second direction, and forming a second isolation layer extending on the conductive layer in the second direction,
etching a portion of the second isolation layer and a portion of the first conductive layer to form the cavity,
forming a first spacer layer on a sidewall of the cavity, the first spacer layer defining a first window area,
forming the collector in the collector region by doping the collector region through the first isolation layer in the first window area,
etching a portion of the first isolation layer to form an empty space in the first isolation layer exposing the collector, wherein the empty space extends, when viewed in the first direction, between the first spacer layer and the substrate, and
forming the monocrystalline base by epitaxially growing monocrystalline material on the collector region to fill the empty space in the first isolation layer.

7. The method according to claim 6, further comprising:
removing the first spacer layer and forming the spacer layer on a sidewall of the cavity.

8. The method according to claim 6, further comprising:
forming the spacer layer on the first spacer layer.

9. The method according to claim 1, wherein the selective epitaxial growing of doped semiconductor material forms the emitter between respective opposing portions of the spacer layer with a gap between the spacer layer and the doped semiconductor material.

10. The method according to claim 1, wherein during the forming of the emitter a cover layer is arranged on an area outside of the emitter, and
wherein during the selective epitaxial growing a third sticking coefficient on the cover layer is zero or a factor 1/10 or less of the second sticking coefficient on the monocrystalline base.

11. The method according to claim 1, wherein the selective epitaxial growing is based on a molecular beam epitaxy or vapor deposition, and
wherein during the selective epitaxial growing a dopant is added to provide a net doping concentration of the emitter (128A) in a range between 1×10²⁰ cm⁻³ and 1×10²¹ cm⁻³.

12. The method according to claim 1, wherein the selective epitaxial growing is based on a silane-based epitaxy, and
wherein the selectivity is provided by predefining a concentration of a silane gas in the silane-based epitaxy and/or using hydrochloric acid.

13. The method according to claim 1, wherein the spacer layer comprises silicon oxide or silicon nitride.

14. A radio frequency bipolar transistor comprising:
a substrate having a main surface,
a collector arranged in the substrate,
a monocrystalline base, wherein the collector faces the monocrystalline base in a first direction perpendicular to the main surface,
a selectively grown monocrystalline emitter, wherein the monocrystalline base is in contact with the selectively grown monocrystalline emitter in the first direction, and
a spacer layer extending from the monocrystalline base in the first direction, wherein the spacer layer is in contact with the selectively grown monocrystalline emitter and surrounds the selectively grown monocrystalline emitter with respect to a second direction parallel to the main surface.

15. The radio frequency bipolar transistor according to claim 14, wherein a net doping concentration of the selectively grown monocrystalline emitter is between 1×10²⁰ cm⁻³ and 1×10²¹ cm⁻³.

16. The radio frequency bipolar transistor according to claim 14, wherein a first section of the spacer layer extends in the first direction and a second section of the spacer layer is in contact with the monocrystalline base and extends in a second direction parallel to the main surface, and
wherein a distance in the second direction between the second section of the spacer layer and a center axis of the radio frequency bipolar transistor is smaller than a distance in the second direction between the first section of the spacer layer and the center axis of the radio frequency bipolar transistor.

17. The radio frequency bipolar transistor according to claim 16, wherein an extension of the selectively grown monocrystalline emitter in the second direction is in a first section of the selectively grown monocrystalline emitter smaller than in a second section of the selectively grown monocrystalline emitter, the first section being closer to the substrate than the second section.

18. The radio frequency bipolar transistor according to claim 14, wherein the radio frequency bipolar transistor is configured for a maximum frequency of oscillation equal to or above 100 GHz.

19. The radio frequency bipolar transistor according to claim 14, wherein a dimension of the selectively grown monocrystalline emitter in a second direction parallel to the main surface of the substrate is in a range between 50 and 500 nm.
